(19) United States
(12) Patent Application Publication
(10) Pub. No.: US 2008/0111140 A1
(43) Pub. Date: May 15, 2008

(54) Light-emitting diode

(75) Inventors: Ching-Huei Wu, San Chung City (TW); Tung-Ching Wu, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/599,595

(22) Filed: Nov. 15, 2006

(51) Int. Cl. H01L 33/00

(52) U.S. Cl. 257/88; 257/E33.001

(57) ABSTRACT

A light-emitting diode comprises: a coupling base; a plurality of light-emitting chips; and a sealant, wherein a plurality of frame pairs having an amount corresponding to that of the light-emitting chips are mounted inside the coupling base. The frame pairs have a plurality of first and second frames having different areas. The light-emitting chips are respectively coupled with a plurality of large-area coupling parts of the first frames, and the light-emitting chips are electrically connected with the second frames, respectively. The coupling base is packaged by the sealant. Accordingly, the volume of the light-emitting diode can be reduced significantly.

### FIELD OF THE INVENTION

The present invention relates to a multi-chip light-emitting diode having significantly reduced volume, and more particularly to a light-emitting diode that has several light-emitting chips mounted thereon.

### BACKGROUND OF THE INVENTION

The existing light-emitting diode is developed for the goals of obtaining small size and enhanced functionality. However, there is a conflict between these two goals. In general, the amount of the circuit or the chip can be increased to provide enhanced functionality. But, the volume of the light-emitting diode is thus changed.

Referring to FIG. 4, the arranged frames of the conventional light-emitting diode are shown. The conventional light-emitting diode has several equally spaced frame pairs 2. Each frame pair 2 comprises a frame 21 and a frame 22, wherein the frame 21 has a recessed cup 23 for coupling with a chip. Therefore, if two or three frame pairs 2 are utilized to enhance the functionality of the light-emitting diode, the volume of the light-emitting diode cannot be reduced due to the distance between every two adjacent frame pairs 2.

In view of the foregoing description, the motive of the present invention is to provide the general public with a light-emitting diode that has the significantly reduced volume.

### SUMMARY OF THE INVENTION

A main object of the present invention is to provide a small-sized light-emitting diode that has the significantly reduced volume.

In order to achieve the above-mentioned object, a light-emitting diode comprises: a coupling base; a plurality of light-emitting chips; and a sealant, wherein a plurality of frame pairs having an amount corresponding to that of the light-emitting chips are mounted inside the coupling base. The frame pairs have a plurality of first and second frames having different areas. The light-emitting chips are respectively coupled with a plurality of large-area coupling parts of the first frames, and the light-emitting chips are electrically connected with the second frames, respectively. The coupling base is packaged by the sealant. Accordingly, the volume of the light-emitting diode can be reduced significantly.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational view showing a preferred embodiment of the present invention.

FIG. 2 is a top view showing the preferred embodiment of the present invention.

FIG. 3 is an assembled, cross-sectional view showing the preferred embodiment of the present invention.

FIG. 4 is a schematic view showing the arranged frames of the conventional light-emitting diode.

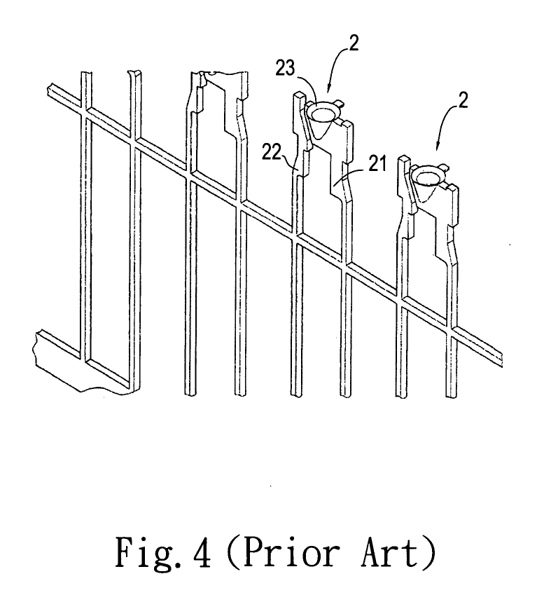

### DETAILED DESCRIPTION OF THE PREFERRED EMBODIMENT

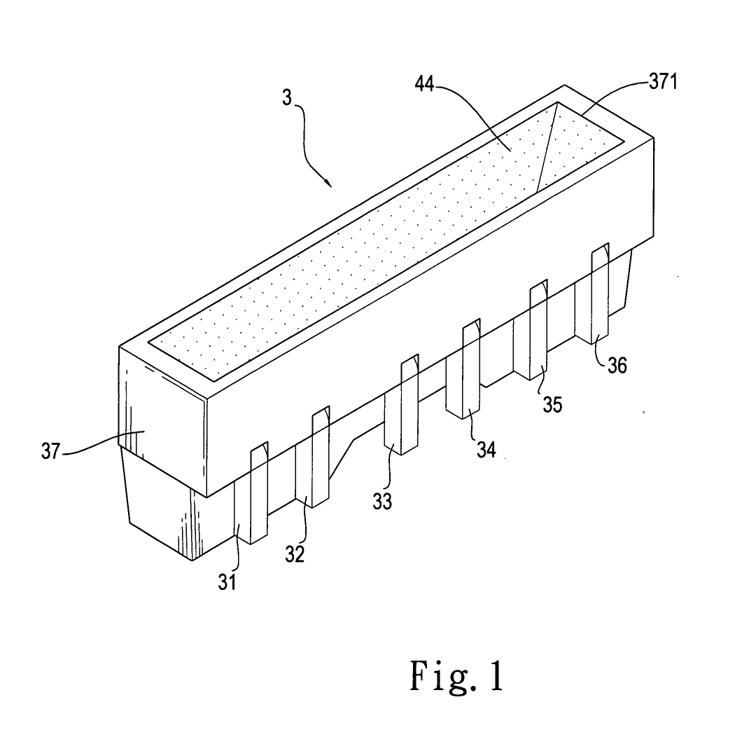

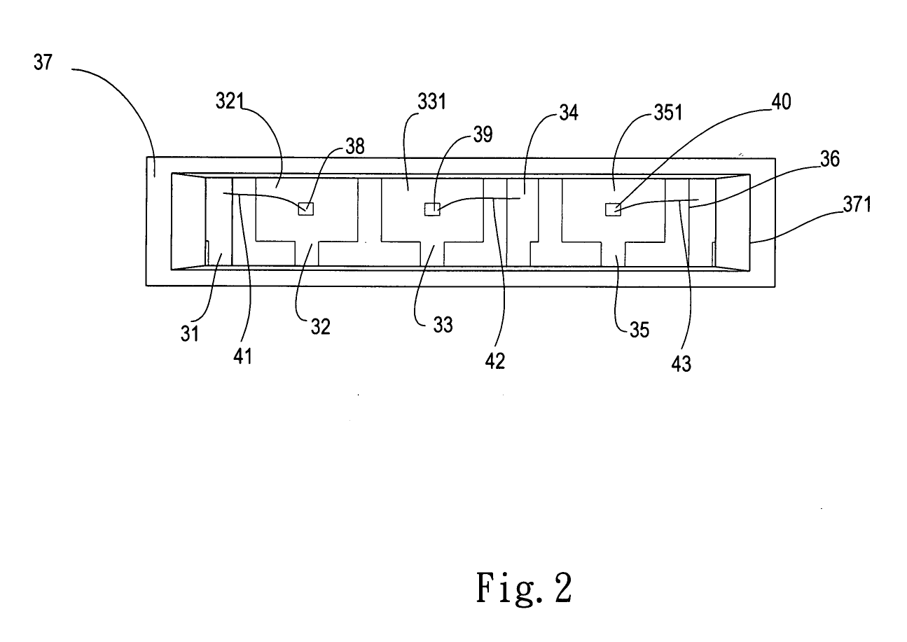

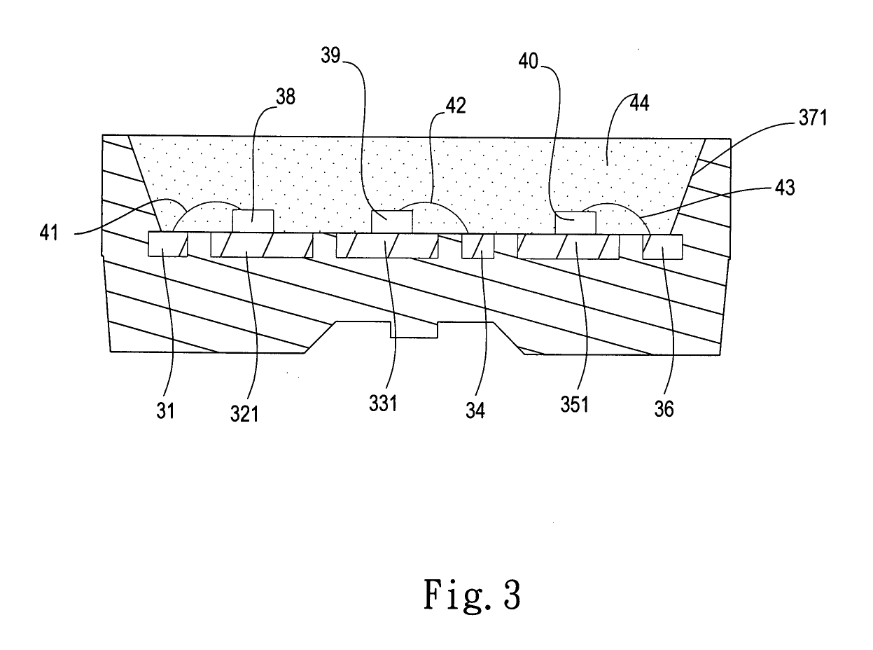

Referring to FIGS. 1 through 3, a light-emitting diode 3 of the present invention comprises a coupling base 37, several light-emitting chips, at least two bonding wires, and a sealant 44. The coupling base 37 has several frame pairs mounted therein, wherein the amount of the frame pairs is corresponding to that of the light-emitting chips. The frames of these frame pairs have different areas. In this preferred embodiment, there are three light-emitting chips 38, 39, and 40. Therefore, the coupling base 37 has six frames 31, 32, 33, 34, 35, and 36. These six frames have different sizes, wherein the frames 31, 34, and 36 are plates having constant upper and lower widths. In addition, the frames 32, 33, and 35 have respective large-area coupling parts 321, 331, and 351 on respective first ends. These six frames including the constant-width frame 31, the frame 32 having the large-area coupling part 321, the frame 33 having the large-area coupling part 331, the constant-width frame 34, the frame 35 having the large-area coupling part 351, and the constant-width frame 36 are arranged in sequence. The respective first ends of these six frames 31 through 36 are located in a trench 371 of the coupling base 37, and covered by the sealant. In addition, the respective second ends of these six frames 31 through 36, which are not covered with the sealant, are stretched out horizontally to be perpendicular to the sealant. Moreover, as disclosed in this preferred embodiment, these respective second ends of these six frames 31 through 36 can be optionally bent by 90 degrees to be parallel to the sealant.

Furthermore, these three light-emitting chips 38, 39, and 40 are coupled to the inside of the trench 371 of the coupling base 37. These light-emitting chips 38, 39, and 40 are coupled with the respective large-area coupling parts 321, 331, and 351 of the frames 32, 33, and 35, respectively. In addition, the light-emitting chips 38, 39, and 40 are electrically connected to the frames 31, 34, and 36 via the bonding wires 41, 42, and 43, respectively. The sealant 44 is filled into the trench 371 of the coupling base 37 for packaging the light-emitting chips 38, 39, and 40 and the bonding wires 41, 42, and 43, which are located inside the trench 371. Thus, the manufacture of the multi-chip, small-sized light-emitting diode that has enhanced functionality and reduced volume is completed.

In summary, the light-emitting diode is provided with several different-sized frames so as to reduce the gaps between every two adjacent frame pairs for significantly reducing the volume of the light-emitting diode that has several light-emitting chips mounted thereon. Accordingly, the light-emitting diode of the present invention satisfies patentability and is thus submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A light-emitting diode comprising:
a coupling base; a plurality of light-emitting chips; and a sealant, wherein a plurality of frame pairs having an amount corresponding to that of said light-emitting chips are mounted inside said coupling base, and said frame pairs have a plurality of first and second frames having different areas, wherein said light-emitting chips are respectively coupled with a plurality of large-area coupling parts of said first frames, and said light-emitting chips are electrically connected with said second frames, respectively, wherein said coupling base is packaged by said sealant, whereby the volume of said light-emitting diode can be reduced significantly.

2. The light-emitting diode of claim 1, wherein said coupling base has a trench to which said first and second frames are coupled for coupling with said light-emitting chips.

3. The light-emitting diode of claim 1, wherein said first and second frames have respective free ends, which are perpendicular to said coupling base.

4. The light-emitting diode of claim 1, wherein said first and second frames have respective free ends, which are bent by an angle to be parallel to said coupling base.
